(19) United States
(12) Patent Application Publication
(10) Pub. No.: US 2025/0020735 A1
(43) Pub. Date: Jan. 16, 2025

(54) METHOD OF DETERMINING FAULT OF POWER SYSTEM

(71) Applicants: ABB SCHWEIZ AG, Baden (CH); HITACHI ENERGY LTD, Zürich (CH)

(72) Inventors: Kai Liu, Beijing (CN); Qi Zhang, Xiamen, Fujian (CN); Simi Valsan, Kerala (IN)

(21) Appl. No.: 18/711,521

(22) PCT Filed: Nov. 18, 2021
(86) PCT No.: PCT/CN2021/131570

§ 371 Date: May 17, 2024

(51) Int. Cl. G01R 31/58; G01R 25/00; G01R 31/08; G01R 31/52

(52) U.S. Cl. CPC G01R 31/58; G01R 25/00; G01R 31/085; G01R 31/52

(57) ABSTRACT

Embodiments of present disclosure provides methods for determining a fault of a power system. Methods include estimating, based on measured electrical quantities at a first position of a power line in the power system, voltages at a second position of the power line, the measured electrical quantities being associated with three phases of the power system and comprising voltages at the first position of the power line. The methods include determining at least one phase angle between the voltages at the first position and the estimated voltages at the second position, and detecting the fault based on the at least one phase angle during a power swing. In a method according to the present disclosure, a three-phase fault during a power swing is identified in a shorter time, and thus the tripping is performed with a faster speed.

### FIELD

Embodiments of present disclosure generally relate to power transmission, and more particularly, to a method of determining a fault of a power system.

### BACKGROUND

In a power system, system disturbances, such as power system faults, line switching, generator disconnection, and the loss of load, may result in power swings. The power system may remain stable and return to a new equilibrium state in experiencing a stable power swing. However, some severe system disturbances may cause eventual loss of synchronism, e.g., between groups of generators. Both of stable and unstable power swings may cause undesired relay operations, which can further aggravate the system disturbances and cause major power outages or power blackouts.

Generally, a power-swing blocking (PSB) function is provided in distance relays to prevent such undesired relay operations during the power swings. In particular, the PSB function can differentiate between the faults and power swings, and block distance relay elements or other relay elements from operating during the power swings.

In the PSB function, the faults that occur during the power swings also should be considered, and thus the PSB has to unblock and allow the relay to operate and remove these faults, such as a three-phase fault. Unfortunately, it is difficult to identify the fault during the power swings, and conventional solutions need a long time to realize the identifying, so as to avoid mistrip. During the power swings, the fault protection with a slow speed has adverse effects on the stability and safety of the power system.

### SUMMARY

Embodiments of the present disclosure provide an improved solution of determining a fault of a power system.

In a first aspect, a method of determining a fault of a power system is provided. The method comprises: estimating, based on measured electrical quantities at a first position of a power line in the power system, voltages at a second position of the power line, the measured electrical quantities being associated with three phases of the power system and comprising voltages at the first position of the power line: determining at least one phase angle between the voltages at the first position and the estimated voltages at the second position; and detecting the fault based on the at least one phase angle during a power swing.

In some embodiments, determining the at least one phase angle between the voltages at the first position and the estimated voltages at the second position comprises: determining a first phase angle between the phase voltage of a first phase at the first position and the estimated phase voltage of the first phase at the second position; and determining a second phase angle between the interphase voltage of a second phase to a third phase at the first position and the estimated interphase voltage of the second phase to the third phase at the second position.

In some embodiments, determining the at least one phase angle between the voltages at the first position and the estimated voltages at the second position comprises: for each of the three phases, determining a phase angle between the phase voltage of the respective phase at the first position and the estimated phase voltage of the same phase at the second position.

In some embodiments, determining the at least one phase angle between the voltages at the first position and the estimated voltages at the second position comprises: for each of three two-phase combinations, determining a phase angle between the interphase voltage of the respective two-phase combination at the first position and the estimated interphase voltage of the same two-phase combination at the second position.

In some embodiments, determining the at least one phase angle between the voltages at the first position and the estimated voltages at the second position comprises: for each of the three phases, determining a first phase angle between the phase voltage of the respective phase at the first position and the estimated phase voltage of the same phase at the second position: for each of three two-phase combinations, determining a second phase angle between the interphase voltage of the respective two-phase combination at the first position and the estimated interphase voltage of the same two-phase combination at the second position; and determining an average angle based on the first phase angles for the three phases and the second phase angles for the three two-phase combinations as the at least one phase angle.

In some embodiments, determining the at least one phase angle between the voltages at the first position and the estimated voltages at the second position comprises: determining a phase angle between a positive-sequence component of the phase voltage of one of the three phases at the first position and a positive-sequence component of the estimated phase voltage of the same phase at the second position.

In some embodiments, detecting the fault based on the at least one phase angle during the power swing comprises: determining a time threshold for each of the at least one phase angle, based on a measured duration of the respective phase angle previously falling within a predefined range, and determining the fault, in the event that a duration of any of the at least one phase angle within the predefined range exceeds the respective time threshold.

In some embodiments, detecting the fault based on the at least one phase angle during the power swing comprises: detecting the fault based on change rates of the at least one phase angle relative to time during a power swing.

In some embodiments, detecting the fault based on the change rates of the at least one phase angle relative to time during the power swing comprises: for each of the at least one phase angle, in response to the respective phase angle falling into a predefined range, determining the change rate of the respective phase angle relative to time: determining a time threshold for each of the at least one phase angle, based on the determined change rate and the predefined range; and determining the fault, in the event that a duration of any of the at least one phase angle within the predefined range exceeds the respective time threshold.

In some embodiments, determining the change rate of the respective phase angle relative to time comprises: in response to the respective phase angle falling into the predefined range, determining an instantaneous change rate of the respective phase angle relative to time.

In some embodiments, determining the change rate of the respective phase angle relative to time comprises: in response to the respective phase angle falling into the predefined range, determining an average change rate of the respective phase angle relative to time in a recent cycle of the power swing, wherein the recent cycle of the power swing comprises a time period from a time point previously entering the predefined range to a time point currently entering the predefined range.

In some embodiments, detecting the fault based on the change rates of the at least one phase angle relative to time during the power swing comprises: for each of the at least one phase angle, in response to the respective phase angle falling into a predefined range, determining an instantaneous change rate of the respective phase angle relative to time; and in response to the instantaneous change rate of any of the at least one phase angle exceeding the predefined threshold, determining the fault.

In some embodiments, estimating the voltages at the second position of the power line comprises: calculating, based on the measured electrical quantities, the voltages at the second position of the power line in a time domain.

In a second aspect, an electronic device is provided. The electronic device comprises: at least one processing unit; and at least one memory coupled to the at least one processing unit and storing instructions executable by the at least one processing unit, the instructions, when executed by the at least one processing unit, causing the device to perform the method according to the first aspect.

In some embodiments, the electronic device comprises a distance relay used in a power system.

In a third aspect, a computer readable storage medium is provided. The computer readable storage medium has computer readable program instructions stored thereon which, when executed by a processing unit, cause the processing unit to perform the method according to the first aspect.

### DESCRIPTION OF DRAWINGS

Drawings described herein are provided to further explain the present disclosure and constitute a part of the present disclosure. The example embodiments of the disclosure and the explanation thereof are used to explain the present disclosure, rather than to limit the present disclosure improperly.

FIG. 1A illustrates a schematic diagram of measured swing impedance and PSB characteristic from a relay in the event that no fault occurs.

FIG. 1B illustrates a schematic diagram of measured swing impedance and PSB characteristic from the relay in the event that a fault occurs during a power swing.

FIG. 2 illustrates a schematic diagram of a simple two-source system connected by a transmission line of impedance according to embodiments of the present disclosure.

FIG. 3 illustrates a schematic diagram of voltage vectors during a power swing according to embodiments of the present disclosure.

FIG. 4 illustrates a waveform diagram of a power system during a power swing according to embodiments of the present disclosure.

FIG. 5 illustrates a schematic diagram of a two-source system when a fault occurs.

FIG. 6 illustrates a flowchart of a method for determining a fault of a power transmission system according to embodiments of the present disclosure.

FIG. 7 illustrates a flowchart of detecting the fault based on change rates of the at least one phase angle relative to time in some embodiments.

FIG. 8A illustrates waveform diagrams of phase angles during a power swing.

FIG. 8B illustrates an enlarged waveform diagram of a phase angle.

FIGS. 9A and 9B illustrate a logic diagram for determining a fault and tripping.

FIG. 10 illustrates an alternative implementation for determining a change rate of a phase angle relative to time.

FIG. 11 illustrates a schematic diagram of a two-source system, in which frequencies of the system are indicated.

FIG. 12 illustrates a schematic block diagram of an example device adapted to implement embodiments of the present disclosure.

Throughout the drawings, the same or similar reference symbols are used to indicate the same or similar elements.

### DETAILED DESCRIPTION OF EMBODIMENTS

Principles of the present disclosure will now be described with reference to several example embodiments shown in the drawings. Though example embodiments of the present disclosure are illustrated in the drawings, it is to be understood that the embodiments are described only to facilitate those skilled in the art in better understanding and thereby achieving the present disclosure, rather than to limit the scope of the disclosure in any manner.

The term “comprises” or “includes” and its variants are to be read as open terms that mean “includes, but is not limited to.” The term “or” is to be read as “and/or” unless the context clearly indicates otherwise. The term “based on” is to be read as “based at least in part on.” The term “being operable to” is to mean a function, an action, a motion or a state can be achieved by an operation induced by a user or an external mechanism. The term “one embodiment” and “an embodiment” are to be read as “at least one embodiment.” The term “another embodiment” is to be read as “at least one other embodiment.” The terms “first,” “second,” and the like may refer to different or same objects. Other definitions, explicit and implicit, may be included below. A definition of a term is consistent throughout the description unless the context clearly indicates otherwise.

Unless specified or limited otherwise, the terms “mounted,” “connected,” “supported,” and “coupled” and variations thereof are used broadly and encompass direct and indirect mountings, connections, supports, and couplings. Furthermore, “connected” and “coupled” are not restricted to physical or mechanical connections or couplings. In the description below, like reference numerals and labels are used to describe the same, similar or corresponding parts in the figures. Other definitions, explicit and implicit, may be included below.

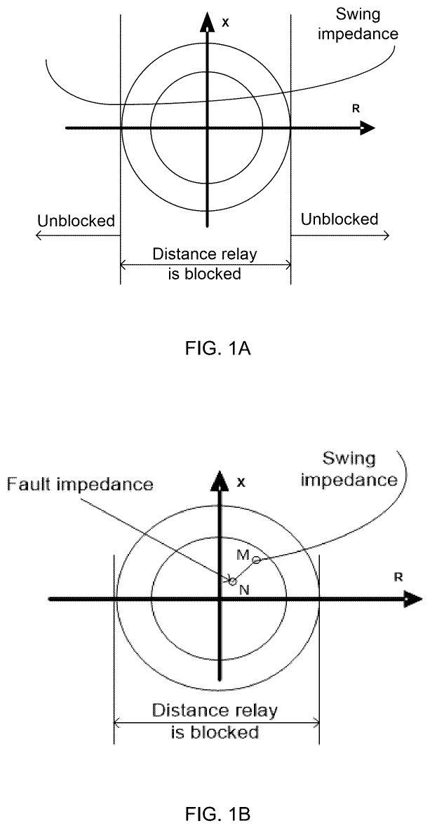

FIG. 1A illustrates a schematic diagram of measured swing impedance and PSB characteristic from a relay in the event that no fault occurs, and FIG. 1B illustrates a schematic diagram of measured swing impedance and PSB characteristic from the relay in the event that a fault occurs during a power swing.

As shown in FIG. 1A, the PSB characteristic may comprise inner and outer characteristics, which are indicated by inner and outer circles respectively. When the time during which the swing impedance stays between the inner and outer characteristic is longer than a predetermined time, the power swing will be detected, and the distance relay will be blocked. In the other areas outside the operation characteristic of the distance relay, the distance relay will be unblocked.

As shown in FIG. 1B, when the swing impedance moves to a point M along a curve, a fault occurs and the fault impedance is maintained at a point N.

It is seen that during the power swing, the impedance enters the operation characteristic of the distance relay, and for the fault (e.g., a three-phase fault), the impedance also enters the operation characteristic. The relay cannot know whether it is a power swing or a fault. In order to identify and remove this fault, conventional solutions are based on an assumption: when fault occurs, the impedance stays in the operation area of the distance relay; and for the power swing, the impedance will enter the operation area of the distance relay and leave the operation area after a waiting time. That is, the relay can determine the fault by waiting for a time long enough. Apparently, the conventional solutions need to wait for a long time to avoid mistrip. Furthermore, parameters of the power system and line are required for determining the waiting time, and thus the setting of the conventional solutions are complicated.

In order to at least partially address the above and other potential problems, embodiments of the present disclosure provide an improved solution for determining a fault of a power transmission system. In such a solution, the fault can be determined based on an angle difference between voltages of two positions of the power line. Thereby, the waiting time for determining the fault is significantly reduced, and thus the trip is performed with a fast speed, improving the safety of the power system.

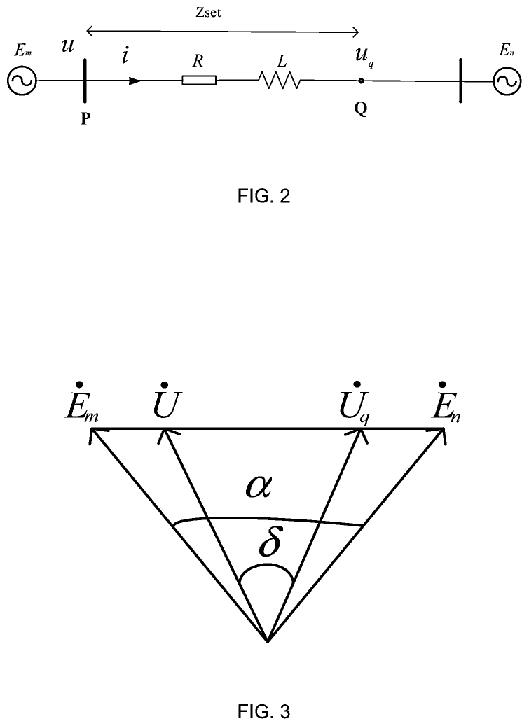

FIG. 2 illustrates a schematic diagram of a simple two-source system connected by a transmission line of impedance according to embodiments of the present disclosure. The system as shown in FIG. 2 is a three-phase power system, and Eₘ and Eₙ refer to the power sources at two ends. A point P indicates a first position of the power line, such as a bus of the power system at the side of the power source Eₘ, a point Q indicates a second position of the power line, such as a pre-set point on the power line, and Zₛₑₜ comprising a resistance R and an inductance L indicates a impedance of the power line between the point P and the point Q. It is to be noted that there are also impedances between the point P and the power source Eₘ and between the point Q and the power source Eₙ, which are not shown in the figure.

Electrical quantities at the point P can be measured or obtained by a relay or other measuring devices arranged at the point P, for example, a relay arranged at or near a bus between the power source and the power line. These electrical quantities comprise voltages, currents and other parameters of the three phases at the point P. The voltages at the point P may be referred to as local voltages, and the voltages at the point Q may be referred to as compensation voltages, which are calculated based on the electrical quantities obtained at the point P. The compensation voltages at the pre-set point Q can be calculated by the equation below:

$${\dot{U}}_{q} = \dot{U} - \dot{I} \times {Z}_{set} \qquad ( 1 )$$

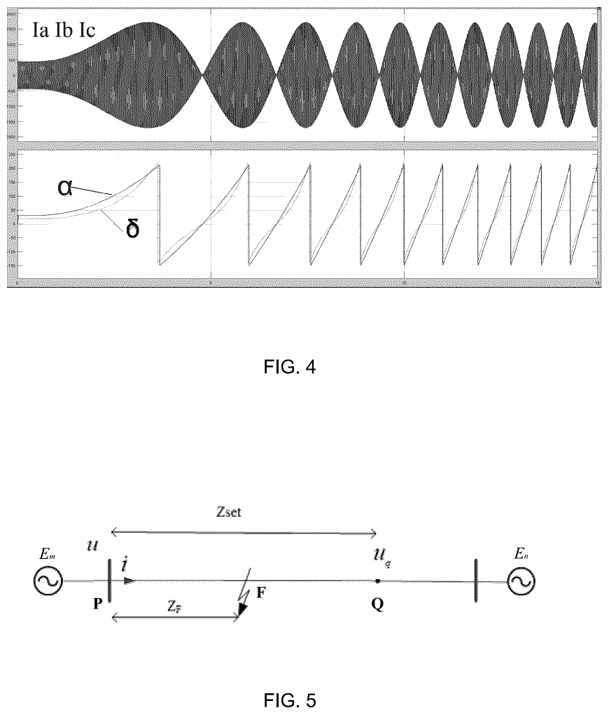

FIG. 3 illustrates a schematic diagram of voltage vectors during a power swing according to embodiments of the present disclosure, and FIG. 4 illustrates waveform diagram of the power system during the power swing according to embodiments of the present disclosure. An angle α indicates a phase angle difference between the power sources Eₘ and Eₙ, and an angle δ indicates a phase angle difference between the local voltage at the point P and the compensation voltage at the pre-set point Q. Specifically, the angle may be represented by the equation below:

$$δ = arg ( {\dot{U}}_{q} / \dot{U} ) \qquad ( 2 )$$

When the power system begins to swing, as the angle α increases, the angle δ also increases. During the power swing, as the angle α changes from 0° to 360° periodically, the angle δ also changes from 0° a to 360° periodically. That is, the angle δ mirrors the angle α, and thus the angle δ can be used as an indicator of the state of the power swing.

FIG. 5 illustrates a schematic diagram of the two-source system of FIG. 2 when a fault (e.g., a three-phase fault) occurs. As shown in the FIG. 5, the fault occurs at a point F on the power line. The fault point F is located between the point P and the point Q, and Z_{F} represent the impedance between the point P and the fault point F. For example, in the event of three-phase fault, an interphase short circuit between the three phases occurs, the impedances Z_{F} and Zₛₑₜ can be assumed to have the substantially same impedance angles, and Z_{F}<Zₛₑₜ. Therefore, in the situation that the three-phase fault occurs, the angle δ may be calculated by the equation as below:

$$δ = arg \frac{{\dot{U}}_{q}}{\dot{U}} = arg \frac{\dot{U} - \dot{I} {Z}_{set}}{\dot{U}} = arg \frac{\dot{I} ( {Z}_{F} - {Z}_{set} )}{\dot{I} {Z}_{F}} = 180 ° \qquad ( 3 )$$

It is seen from above, when the internal three-phase fault occurs, the angle δ will be maintained at 180 degree, hereafter referred to as a fault angle δ. However, if there is only the power swing, the angle δ is changed periodically from 0 to 360 degree. It is noted that 180 degree of the fault angle δ is only exemplary, and due to the arrangement of the line impedance or the other errors, the impedances Z_{F} and Zₛₑₜ generally may have different impedance angles, and thus the angle δ in the fault may also be any other angles, which are higher or lower than 180 degree.

Moreover, such change in the angle δ may also be present in other types of faults other than the three-phase fault. For example, when a single-phase fault or a two-phase fault occurs at some positions of the power line, e.g., positions of the power line near the point P, the angle δ will also be changed to and maintained at a fault angle δ. Based on this discovery, the fault of the power system can be distinguished from the power swing effectively.

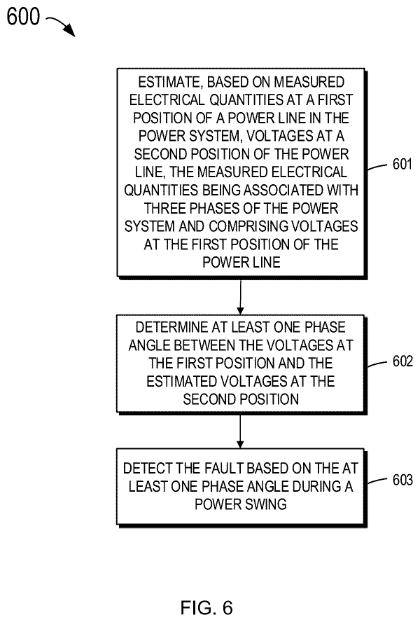

On the basis of the above property discovered by the inventor, an improved method is proposed to identify the fault during the power swing rapidly and thus trip with a higher speed when the fault occurs. FIG. 6 illustrates a flowchart of a method 600 for determining a fault of a power transmission system according to embodiments of the present disclosure. The method can be performed by a processing unit or a controller of an electronic device such as the relay as mentioned above. For example, in some embodiments, the processing unit for performing the method may be an integral part of the existing processor or a control unit arranged in the relay. In some alternative embodiments, the processor for performing the method may also be another processor independent of the existing processor of the relay.

In some other alternative embodiments, the processor may also be a processor of a device such as a computer located outside the relay. Actually, any suitable processor that can perform the method below may be used.

As shown in FIG. 6, at block 601, based on measured electrical quantities at a first position of a power line in the power system, voltages at a second position of the power line are estimated. The measured electrical quantities are associated with three phases of the power system and comprise voltages at the first position of the power line. For example, the first position may be the point P (e.g., a bus) of FIG. 2, and the second position may be the point Q (e.g., a pre-set point on the power line) of FIG. 2. As an example, the distance between the first and the second positions may be 80˜90% of the total length of the power line of the power system. However, the first and the second positions may be also any suitable positions in the power system. The relay such as a mho relay arranged at the first position (e.g., the point P) or any other measuring device can measure the electrical quantities at the first position. These electrical quantities comprise voltages at the first position, e.g., phase voltages and interphase voltages of the three phases. Furthermore, the electrical quantities also comprise other electrical quantities associated with the three phases, so as to be used for estimating the voltages at the second position. By means of the equation (1) and the measured electrical quantities at the first position, the voltages at the second position can be estimated. For example, based on a phase voltage and current (e.g., of phase A) at the point P and the impedance Zₛₑₜ between the points P and Q, a phase voltage (e.g., of phase A) at the point Q is calculated by the equation (1). Similarly, phase voltages of phase B and C at the point Q can be calculated, thus also obtaining interphase voltages of phases A and B, B and C, or C and A.

At block 602, at least one phase angle between the voltages at the first position and the estimated voltages at the second position is determined. For example, since the voltages of phase A at the points P and Q are obtained from block 601, a phase angle δₐ between the voltages of phase A at the first and second positions (e.g., the points P and Q) can be simply calculated and determined. Similarly, phase angles δ_{b}, δ_{c}, δ_{ab}, δ_{bc} and δ_{ca} of other phase voltages and interphase voltages can be obtained.

In some embodiments, the determining of the at least one phase angle between the voltages at the first position and the estimated voltages at the second position comprises: determining a first phase angle between the phase voltage of a first phase at the first position and the estimated phase voltage of the first phase at the second position; and determining a second phase angle between the interphase voltage of a second phase to a third phase at the first position and the estimated interphase voltage of the second phase to the third phase at the second position. For example, it is possible to only calculate the phase angles δₐ between the voltages of phase A at the first and second positions and phase angle δ_{bc} between the interphase voltages of phase B to phase C at the first and second positions, since the phase angles δₐ and δ_{bc} are sufficient to show the state of all the three phases of the power system during the power swing. Alternatively, it is also possible to obtain only the phase angles δ_{b} and δ_{ca} or only the phase angles δ_{c} and δ_{ab}. In this way, instead of determining all the phase angles δₐ, δ_{b}, δ_{c}, δ_{ab}, δ_{bc} and δ_{ca}, only two phase angles are calculated, which reduces works for calculating and subsequently evaluating the phase angles, thereby accelerating the speed of fault determination.

In some embodiments, determining the at least one phase angle between the voltages at the first position and the estimated voltages at the second position comprises: for each of the three phases, determining a phase angle between the phase voltage of the respective phase at the first position and the estimated phase voltage of the same phase at the second position. For example, it is possible to calculate the phase angles δₐ, δ_{b} and δ_{c} as the at least one phase angle. In some embodiments, determining the at least one phase angle between the voltages at the first position and the estimated voltages at the second position comprises: for each of three two-phase combinations, determining a phase angle between the interphase voltage of the respective two-phase combination at the first position and the estimated interphase voltage of the same two-phase combination at the second position. For example, it is possible to calculate the phase angles δ_{ab}, δ_{bc} and δ_{ca}, as the at least one phase angle. In the both implementation, instead of determining all the phase angles δₐ, δ_{b}, δ_{c}, δ_{ab}, δ_{bc} and δ_{ca}, only three phase angles are calculated, which reduces works for calculating and subsequently evaluating the phase angles.

In some embodiments, the determining of the at least one phase angle between the voltages at the first position and the estimated voltages at the second position comprises: for each of the three phases, determining a first phase angle between the phase voltage of the respective phase at the first position and the estimated phase voltage of the same phase at the second position: for each of three two-phase combinations, determining a second phase angle between the interphase voltage of the respective two-phase combination at the first position and the estimated interphase voltage of the same two-phase combination at the second position; and determining an average angle based on the first phase angles for the three phases and the second phase angles for the three two-phase combinations as the at least one phase angle. Specifically, the average of all the phase angles can be used for evaluating the fault during the power swing, and can be calculated by the following equation:

$${δ}_{Average} = ( {δ}_{a} + {δ}_{b} + {δ}_{c} + {δ}_{ab} + {δ}_{bc} + {δ}_{ca} ) / 6 \qquad ( 4 )$$

In this way, the subsequent evaluation or fault determination can be done for a single phase angle, which simplifies the subsequent work.

In some embodiments, the determining of the at least one phase angle between the voltages at the first position and the estimated voltages at the second position comprises: determining a phase angle between a positive-sequence component of the phase voltage of one of the three phases at the first position and a positive-sequence component of the estimated phase voltage of the same phase at the second position. Specifically, based on all the phases voltages of the three phases at the first position (e.g., the point P), the positive-sequence component of any phase at the first position can be obtained according to the approach known in the art, and similarly, the positive-sequence component of the phase at the second position can be obtained. Thereby, the phase angle between the positive-sequence components of a phase voltage (e.g., of phase A, B or C) at the first and second positions can be determined and used for evaluating the fault during the power swing. As a result, the subsequent evaluation can be done for a single phase angle, and thus the fault determination is simplified.

At block 603, the fault is detected based on the at least one phase angle during the power swing. For example, as discussed above for the equation (3), in the event of a fault, the phase angles will be changed to and then maintained at 180 degree. Therefore, the fault can be detected rapidly based on the change of the phase angles δₐ, δ_{b}, δ_{c}, δ_{ab}, δ_{bc} and δ_{ca}. In some embodiments, the fault can be detected by the the phase angles δₐ and δ_{bc}. Alternatively, it is also possible to detect the fault by means of the the phase angles δ_{b} and δ_{ca}, the phase angels δ_{c} and dah, the phase angles δₐ, δ_{b}, and δ_{c}, or the phase angles δ_{ab}, δ_{bc} and δ_{ca}. In some embodiments, the fault can be detected by the average of all the phase angles δₐ, δ_{b}, δ_{c}, δ_{ab}, δ_{bc} and δ_{ca}. In some embodiments, the fault can be detected by the phase angle between the positive-sequence voltage components of a phase (e.g., the phase A, B or C) at the first and second positions.

Compared with the conventional solutions, the fault detection described with respect to the method 600 may be achieved far faster, without waiting for a long time corresponding to the time of the swing impedance entering and leaving the operation area of the relay, thus improving the stability and safety of the power system. Furthermore, in the method 600, the parameters of the power system and line required for predetermining the time of the swing impedance entering and leaving the operation area are advantageously omitted, which simplifies the fault detection.

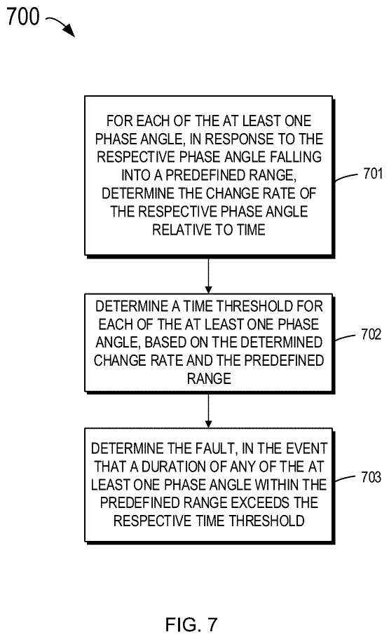

FIG. 7 illustrates a flowchart of detecting the fault based on change rates of the at least one phase angle relative to time in some embodiments. In some embodiments, detecting the fault based on the at least one phase angle during the power swing comprises: detecting the fault based on the change rates of the at least one phase angle relative to time during the power swing. As shown in FIG. 7, at block 701, for each of the at least one phase angle, in response to the respective phase angle falling into a predefined range, the change rate of the respective phase angle relative to time is determined. At block 702, based on the determined change rate and the predefined range, a time threshold for each of the at least one phase angle is determined. At block 703, in the event that a duration of any of the at least one phase angle within the predefined range exceeds the respective time threshold, the fault is determined.

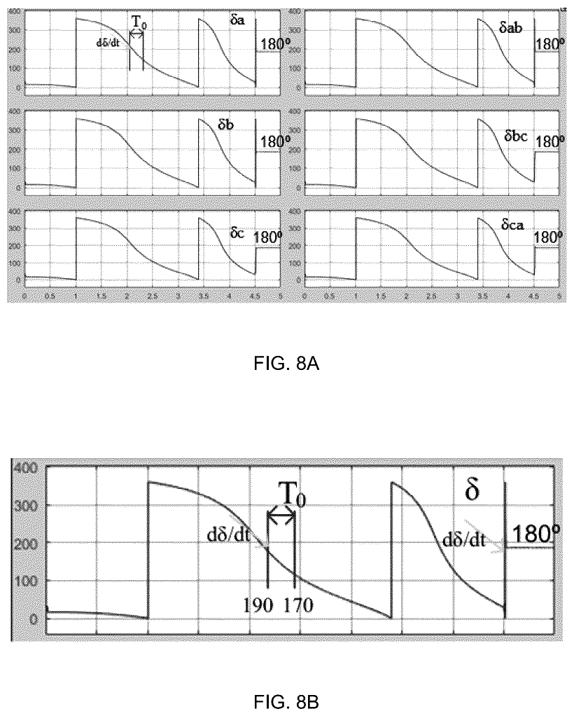

For the purpose of illustration, FIG. 8A illustrates waveform diagrams of phase angles δₐ, δ_{b}, δ_{c}, δ_{ab}, δ_{bc} and δ_{ca} during the power swing, and FIG. 8B illustrates an enlarged waveform diagram of the phase angle δₐ. As shown in FIGS. 8A and 8B, during the power swing, each of the phase angles δₐ, δ_{b}, δ_{c}, δ_{ab}, δ_{bc} and δ_{ca} varies from 0 degree to 360 degree in each cycle. As shown in a period after 4.5 s, when a fault occurs, all of the phase angles are quickly changed to and maintained at 180 degree.

In order to identify the fault, an angle range [δ₁, δ₂] comprising 80 degree therein may be predefined. For example, the angle range [δ₁, δ₂] is [170, 190], i.e., a range between 170 degree and 190 degree as shown in FIG. 8B. Alternatively, the angle range [δ₁, δ₂] may also be any other suitable range. Apparently, if the fault occurs, the phase angles δₐ, δ_{b}, δ_{c}, δ_{ab}, δ_{bc} and δ_{ca} certainly fall into the predefined range. Furthermore, it is appreciated that during the power swing, the phase angles also will enter this predefined range. Once the respective phase angle falls into the predefined range, the change rate of the respective phase angle relative to time is determined. As shown in FIG. 8B, in some embodiments, the change rate may be an instantaneous change rate dδ/dt of the respective phase angle relative to time when the respective phase angle enters the predefined range. Then, a reference threshold T₀ may be calculated by the equation below:

$${T}_{0} = \frac{{δ}_{2} - {δ}_{1}}{d δ / dt} \qquad ( 5 )$$

To improve the reliability of the fault detection and avoid mistrip, the time threshold T may be greater than the reference threshold T₀, and thus can be calculated by the following equation:

$$T = {k}_{rel} \times {T}_{0} \qquad ( 6 )$$

For example, kᵣₑₗ may be 1.2˜2.0, ensuring T>T₀.

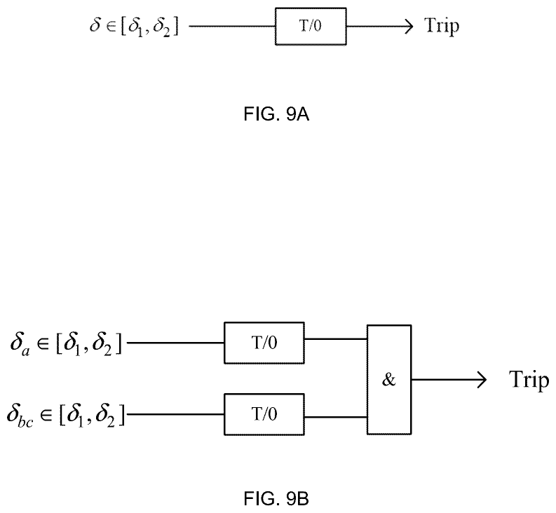

FIGS. 9A and 9B show a logic diagram for determining the fault and tripping. As shown in FIG. 9A, if the respective phase angle δ remains in the range [δ₁, δ₂] (e.g. [170, 190]) for the time threshold T, the three phase fault may be determined. For example, the logic shown in FIG. 9A may be implemented for all the phase angles δₐ, δ_{b}, δ_{c}, δ_{ab}, δ_{bc} and δ_{ca}, and once a duration of any one of these phase angles falling into the range [δ₁, δ₂] reaches or exceeds the time threshold T, the three phase fault is determined. As shown in FIG. 9B, in some embodiments, if any of the phase angles δₐ and one remains in the range [δ₁, δ₂] (e.g. [170, 190]) for the time threshold T, the three phase fault may be determined. Alternatively, if any of the phase angles on and δ_{ca} or any of the phases angles δ_{c} and δ_{ab} remains in the range [δ₁, δ₂] (e.g. [170, 190]) for the time threshold T, the three phase fault may be determined. Alternatively, if any of the phase angles δₐ, on and δ_{c} or any of the phases angles δ_{ab}, δ_{bc} and δ_{ca} remains in the range [δ₁, δ₂] (e.g. [170, 190]) for the time threshold T, the three phase fault may be determined. Similarly, by means of the phase angle associated with the positive-sequence voltage component or the average of all the phase angles δₐ, δ_{b}, δ_{c}, δ_{ab}, δ_{bc} and δ_{ca}, the three phase fault may be also determined.

It is seen from above, the reference threshold T₀ represents a predicted time required for the phase angle to pass through the predefined range (e.g., [170, 190]) during the power swing. Generally, the predefined range (e.g., [170, 190]) is a relatively small interval, and thus the instantaneous change rate dδ/dt can be regarded as a constant in this interval. In this situation, the calculated T₀ has a relatively high accuracy, and is very close to the real-time interval required for the phase angle passing through the predefined range during the power swing. Moreover, with the coefficient kᵣₑₗ, the time threshold T is slightly greater than T₀ to ensure a margin. Therefore, when the time of the phase angle within the predefine degree range reaches the time threshold T, it is enough to determine that the phase angle is maintained at 180 degree, i.e., the fault occurs. It is noted that this time threshold T is not a constant value, and is calculated in real time. In particular, in the event of the fault, the instantaneous change rate dδ/dt of the respective phase angle is a large value, and thus the time threshold T calculated in real time by the equations (5) and (6) is very small. For example, when a fault occurs, the phase angle suddenly changes to 180 degree from other value such as 30 degree in a very short time (e.g., 20 ms). The reference threshold T₀ is obtained by the equation (5) as following: dδ/dt=(180−30)/0.02=7500 degree/s, and T₀=(190-170)/7500=27 ms. Assuming kᵣₑₗ=1.48, the time threshold may be calculated by the equation (6) as 40 ms. That is, according to the solution of present invention, the duration of tripping the fault may be very short, for example, as short as tens milliseconds. In contrast, the conventional solutions typically need 2 s or even longer to determine and trip the fault, since the predetermined time of the conventional solutions should be set longer than the maximum time that the impedance stays in the operation area of the relay during the power swing.

Moreover, the solution of the present invention provides additional advantages on avoiding the mistrip. In particular, for the reverse close fault and forward external fault, the phase angle δ=0. Thus, the phase angle δ will not enter the relatively small predefined range [δ₁, δ₂] (e.g., [170, 190]). In this way, the present solution does not mistrip for external fault.

Furthermore, in the embodiments that the change rate of the phase angle is considered as the instantaneous change rate do dt, the reference threshold T₀ and the time threshold T are independent of the period or cycle of the power swing, thus providing an advantage of the operation speed independent of the period or cycle of the power swing. That is, no matter how long the power swing period (e.g., typically 300 ms to 3 s), the duration required for tripping is only associated with the instantaneous change rate do dt when the fault occurs.

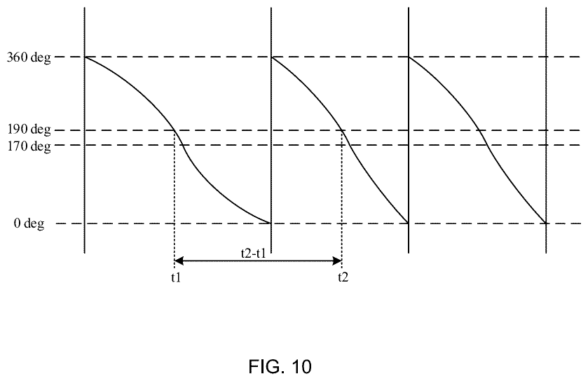

FIG. 10 illustrates an alternative implementation for determining the change rate of the phase angle relative to time. In some embodiments, in response to the respective phase angle δₐ, δ_{b}, δ_{c}, δ_{ab}. δ_{bc} or δ_{ca} falling into the predefined range (e.g., [170, 190]), an average change rate of the respective phase angle relative to time in a recent cycle of the power swing is determined. The recent cycle of the power swing comprises a time period from a time point previously entering the predefined range to a time point currently entering the predefined range. For example, as shown in FIG. 10, when the phase angle δ reaches the 190 degree at the time point t1, the phase angle δ enters the predefined range [170, 190] and the time point t1 may be recorded, and then when the phase angle δ reaches the 190 degree again at the time point t2, the time point t2 may be recorded. Based on the recorded time points t1 and t2, a duration of a recent cycle of the power swing is determined. The average change rate of the phase angle δ relative to time in the recent cycle can be calculated as 360/(t2−t1). With the average change rate of the phase angle δ in the recent cycle, the time during which the phase angle δ stays in the predefined range also can be estimated. In particular, in a calculation similar to the equations (5) and (6), the reference threshold T₀ and the time threshold T can be obtained, wherein the equation (5) may be replaced with T₀=(δ₂−δ₁)*(t2−t1)/360. In this implementation, the time required for the fault detection will vary according to the real-time period of the power swing. For example, assuming that δ₂ is 190 degree, δ₁ is 170 degree and kᵣₑₗ is 1.2, for 1 s of a swing period (i.e., t2-t1=1 s), the time required for tripping is T=1.2*55 ms=66 ms, for 300 ms of a swing period (i.e., t2-t1=300 ms), the required time is T=1.2*17 ms=20 ms, and for 3 s of a swing period (i.e., t2−t1=3 s), the required time is T=1.2*167 ms=200 ms. It is seen that compared with the conventional solutions, this implementation trips the line with the fault at a faster speed, thereby improving the stability of the power system.

Instead of the equation (5), the reference threshold T₀ and thus the time threshold T also may be determined in other ways, so as to determine the fault. In some embodiments, detecting the fault based on the at least one phase angle during the power swing comprises: determining a time threshold for each of the at least one phase angle, based on a measured duration of the respective phase angle previously falling within a predefined range, and determining the fault, in the event that a duration of any of the at least one phase angle within the predefined range exceeds the respective time threshold. For example, during the power swing, the time points of the phase angle δ entering and leaving the predefined range [δ₁, δ₂] (e.g., [170, 190]) for a first time can be measured, and thus the duration of the phase angle δ falling within the predefined range is measured or determined. The measured or determined duration can be directly used as the reference threshold T₀, thereby determining the time threshold T by the equation (6). When entering the predefined range [δ₁, δ₂] for a second time, the determined time threshold T is used for judging the fault in a similar manner to the embodiments of FIG. 9A. That is, if the duration of the phase angle δ within the predefined range [δ₁, δ₂] exceeds the time threshold T, it is determined that a fault has occurred, otherwise it is determined that no fault has occurred. In the event of no fault, the time points of the phase angle δ entering and leaving the predefined range [δ₁, δ₂] (e.g., [170, 190]) for the second time can be measured, thereby determining the duration. The determined duration is used for updating the reference threshold T₀, so as to help judge the fault when entering the predefined range [δ₁, δ₂] for a third time. In the subsequent period of the power swing, the fault determination can be done similarly. It is note that in the above detection, during the first cycle of the power swing, the reference threshold T₀ may be defined in other ways, e.g., an initial value of T₀ may be predefined based on historical data, or may be calculated based on the instantaneous change rate of the phase angle δ. Alternatively, during the first cycle of the power swing, the fault may also be determined by other means that do not require the use of T₀. In this implementation, the calculation for the change rate of phase angle is avoided, which reduces the load of the processor and speeds up the fault determination.

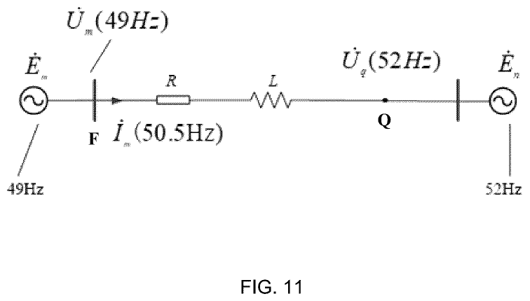

FIG. 11 illustrates a schematic diagram of the two-source system, in which the frequencies of the power system are indicated. In general, during the power swing, the frequencies of the generators or the power sources are not the fundamental frequency anymore. For example, as shown in the FIG. 11, the frequency of Eₘ is 49 Hz, the frequency of Eₙ is 52 Hz, and the frequency of the current Iₘ is 50.5 Hz. Since the frequencies of the current and voltage are not the same, it may be not accurate to calculate the voltages of the second position (e.g., the point Q) of the power line in frequency domain by means of the equation (1). In some embodiments, estimating the voltages at the second position (e.g., the point Q) of the power line comprises: calculating, based on the measured electrical quantities at the first position (e.g., the point P), the voltages at the second position of the power line in a time domain. When calculating the voltages at the second position in the time domain, the equation (1) may be replaced by the equation below:

$${u}_{q} = {u}_{m} - ( Ri + L \frac{di}{dt} ) \qquad ( 7 )$$

When implementing the calculation in the time domain, the voltages and currents at the first position can be sampled and obtained. These sampled voltages and currents can be used for calculating the voltages at the second position by the equation (7). After obtaining the voltages at the first and second positions, by means of the Fourier transform, the real and imaginary parts of the respective voltage at the first position and the real and imaginary parts of the respective voltage at the second position can be calculated. Thereby, the at least one phase angle between the voltages at the first and second positions and thus the change rate of the at least one phase angles relative to time can be further calculated.

In the previous discussion, the approach of setting T₀ and T based on the change rate of the phase angle δ to identify the fault has been discussed. However, it is appreciated that identifying the fault based on the change rate of the phase angle δ can be implemented in other suitable approach. In some embodiments, detecting the fault based on the change rates of the at least one phase angle relative to time during the power swing comprises: for each of the at least one phase angle, in response to the respective phase angle falling into a predefined range comprising 180 degree therein, determining an instantaneous change rate of the respective phase angle relative to time; and in response to the instantaneous change rate of any of the at least one phase angle exceeding the predefined threshold, determining the fault.

Specifically, since the phase angle δ will be suddenly changed to 180 degree when the fault occurs, the change rate of the phase angle δ will increase significantly in the case of the fault. Therefore, the threshold of the change rate may be predefined for monitoring the change of the phase angle δ, and should be much larger than the change rate of the phase angle during the normal power swing. When the phase angle enters the predefined range [δ₁, δ₂] (e.g., [170, 190]), the instantaneous change rate of the phase angle will be compared with the threshold, and the fault can be determined if the instantaneous change rate exceeds the threshold. In this manner, identifying the fault is implemented by comparing the real-time change rate with the threshold without the waiting time T, and thus the fault detection only needs the time for measurement and calculation, which further reduce the time required for fault tripping during the power swing. However, when the fault occurs during the predefined range [δ₁, δ₂], this approach may not detect the abnormal increase in the change rate of the phase angle δ, and fails to work. In this situation, the fault occurs during the predefined range [δ₁, δ₂] may be detected by the other ways, for example, the above approach of setting T₀ and T based on the change rate of the phase angle δ, or conventional solutions in which a waiting time the impedance leaves the operation area of the distance relay is needed.

Furthermore, in the proposed solutions of identifying the fault based on the change rate of the phase angle δ, the fault may be missed in some cases. For example, if the fault occurs at the first and second positions (e.g., the points P and Q in the FIG. 2), since the voltages at the first position or at the second position are zero, the phase angle δ in the equation (2) cannot be obtained, and thus the proposed solutions cannot work under this condition. Therefore, for the fault occurs at the point P or Q in the FIG. 2, the fault may be detected in other ways, e.g., the conventional solutions with slow protection speed. That is, the proposed method of the present invention may be performed in parallel with the conventional solutions to achieve a reliable and efficient fault protection during the power swing.

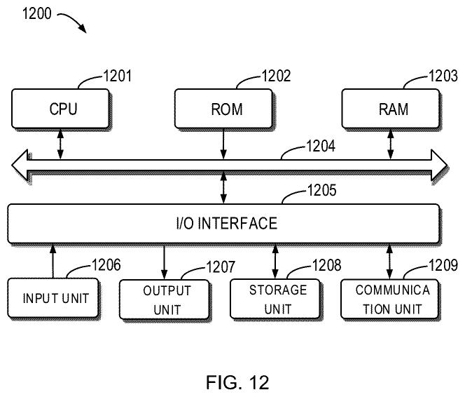

According to other aspects of the present disclosure, an electronic device that can implement embodiments of the present disclosure as mentioned above is provided. FIG. 12 shows a schematic block diagram of an example device 1200 adapted to implement embodiments of the present disclosure. For example, the fault detecting device may be implemented by the device 1200. As shown therein, the device 1200 comprises a central processing unit (CPU) 1201 that may perform various appropriate actions and processing based on computer program instructions stored in a read-only memory (ROM) 1202 or computer program instructions loaded from a storage section 1208 to a random access memory (RAM) 1203. In the RAM 1203, various programs and data needed for operations of the device 1200 are further stored. The CPU 1201, ROM 1202 and RAM 1203 are connected to each other via a bus 1204. An input/output (I/O) interface 1205 is also connected to the bus 1204.

The following components in the device 1200 are connected to the I/O interface 1205: an input unit 1206, such as a keyboard, a mouse and the like: an output unit 1207, such as various kinds of displays and a loudspeaker, etc.: a memory unit 1208, such as a magnetic disk, an optical disk, etc.: a communication unit 1209, such as a network card, a modem, a wireless communication transceiver, etc. The communication unit 1209 allows the device 1200 to exchange information/data with other devices through a computer network such as the Internet and/or various kinds of telecommunications networks.

Various processes and processing described above, e.g., the methods 600, may be executed by the processing unit 1201. For example, in some embodiments, the method 600 may be implemented as a computer software program that is tangibly embodied on a machine readable medium, e.g., the storage unit 1208. In some embodiments, part or all of the computer programs may be loaded and/or mounted onto the device 1200 via ROM 1202 and/or communication unit 1209. When the computer program is loaded to the RAM 1203 and executed by the CPU 1201, one or more acts of the method 600 as described above may be executed.

In some embodiments, the electronic device may be a distance relay such as a mho relay as mentioned above. With the methods according to embodiments of the present disclosure embedded in the distance relay, the reliability of the power transmission line can be significantly improved.

According to another aspect of the present disclosure, a computer readable storage medium (or media) having computer readable program instructions thereon for performing aspects of the present disclosure is provided.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the scenario involving the remote computer, the remote computer may be connected to the user's computer through any type of network, including a local area network (LAN) or a wide area network (WAN), or the connection may be made to an external computer (for example, through the Internet using an Internet Service Provider). In some embodiments, the electronic circuitry can be customized by utilizing state information of the computer readable program instructions, for example, programmable logic circuitry, field-programmable gate arrays (FPGA), or programmable logic arrays (PLA). The electronic circuitry may execute the computer readable program instructions, in order to perform aspects of the present disclosure.

Aspects of the present disclosure are described herein with reference to flowchart illustrations and/or block diagrams of methods, device (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can enable a computer, a programmable data processing apparatus, and/or other devices to function in a particular manner, such that the computer readable storage medium having instructions stored therein comprises an article of manufacture, which includes instructions implementing aspects of the function/act specified in block or blocks of the flowchart and/or block diagram.

The computer readable program instructions may also be loaded onto a computer, other programmable data processing apparatuses, or other device to cause a series of operational steps to be performed on the computer, other programmable data processing apparatuses or other devices to produce a computer implemented process, such that the instructions which execute on the computer, other programmable data processing apparatuses, or other devices implement the functions/acts specified in block or blocks of the flowchart and/or block diagram.

It should be appreciated that the above detailed embodiments of the present disclosure are only to exemplify or explain principles of the present disclosure and not to limit the present disclosure. Therefore, any modifications, equivalent alternatives and improvement, etc. without departing from the spirit and scope of the present disclosure shall be comprised in the scope of protection of the present disclosure. Meanwhile, appended claims of the present disclosure aim to cover all the variations and modifications falling under the scope and boundary of the claims or equivalents of the scope and boundary.

1. A method of determining a fault of a power system, comprising:
estimating, based on measured electrical quantities at a first position of a power line in the power system, voltages at a second position of the power line, the measured electrical quantities being associated with three phases of the power system and comprising voltages at the first position of the power line;
determining at least one phase angle between the voltages at the first position and the estimated voltages at the second position; and
detecting the fault based on the at least one phase angle during a power swing.

2. The method of claim 1, wherein determining the at least one phase angle between the voltages at the first position and the estimated voltages at the second position comprises:
determining a first phase angle between the phase voltage of a first phase at the first position and the estimated phase voltage of the first phase at the second position; and
determining a second phase angle between the interphase voltage of a second phase to a third phase at the first position and the estimated interphase voltage of the second phase to the third phase at the second position.

3. The method of claim 1, wherein determining the at least one phase angle between the voltages at the first position and the estimated voltages at the second position comprises:
for each of the three phases, determining a phase angle between the phase voltage of the respective phase at the first position and the estimated phase voltage of the same phase at the second position.

4. The method of claim 1, wherein determining the at least one phase angle between the voltages at the first position and the estimated voltages at the second position comprises:
for each of three two-phase combinations, determining a phase angle between the interphase voltage of the respective two-phase combination at the first position and the estimated interphase voltage of the same two-phase combination at the second position.

5. The method of claim 1, wherein determining the at least one phase angle between the voltages at the first position and the estimated voltages at the second position comprises:
for each of the three phases, determining a first phase angle between the phase voltage of the respective phase at the first position and the estimated phase voltage of the same phase at the second position;
for each of three two-phase combinations, determining a second phase angle between the interphase voltage of the respective two-phase combination at the first position and the estimated interphase voltage of the same two-phase combination at the second position; and
determining an average angle based on the first phase angles for the three phases and the second phase angles for the three two-phase combinations as the at least one phase angle.

6. The method of claim 1, wherein determining the at least one phase angle between the voltages at the first position and the estimated voltages at the second position comprises:
determining a phase angle between a positive-sequence component of the phase voltage of one of the three phases at the first position and a positive-sequence component of the estimated phase voltage of the same phase at the second position.

7. The method of claim 1, wherein detecting the fault based on the at least one phase angle during the power swing comprises:
determining a time threshold for each of the at least one phase angle, based on a measured duration of the respective phase angle previously falling within a predefined range, and
determining the fault, in the event that a duration of any of the at least one phase angle within the predefined range exceeds the respective time threshold.

8. The method of claim 1, wherein detecting the fault based on the at least one phase angle during the power swing comprises:
detecting the fault based on change rates of the at least one phase angle relative to time during a power swing.

9. The method of claim 8, wherein detecting the fault based on the change rates of the at least one phase angle relative to time during the power swing comprises:
for each of the at least one phase angle, in response to the respective phase angle falling into a predefined range, determining the change rate of the respective phase angle relative to time;
determining a time threshold for each of the at least one phase angle, based on the determined change rate and the predefined range; and
determining the fault, in the event that a duration of any of the at least one phase angle within the predefined range exceeds the respective time threshold.

10. The method of claim 9, wherein determining the change rate of the respective phase angle relative to time comprises:
in response to the respective phase angle falling into the predefined range, determining an instantaneous change rate of the respective phase angle relative to time.

11. The method of claim 9, wherein determining the change rate of the respective phase angle relative to time comprises:
in response to the respective phase angle falling into the predefined range, determining an average change rate of the respective phase angle relative to time in a recent cycle of the power swing, wherein the recent cycle of the power swing comprises a time period from a time point previously entering the predefined range to a time point currently entering the predefined range.

12. The method of claim 8, wherein detecting the fault based on the change rates of the at least one phase angle relative to time during the power swing comprises:
for each of the at least one phase angle, in response to the respective phase angle falling into a predefined range comprising, determining an instantaneous change rate of the respective phase angle relative to time; and
in response to the instantaneous change rate of any of the at least one phase angle exceeding a predefined threshold, determining the fault.

13. The method of claim 1, wherein estimating the voltages at the second position of the power line comprises:
calculating, based on the measured electrical quantities, the voltages at the second position of the power line in a time domain.

14. An electronic device, comprising:
at least one processing unit; and
at least one memory coupled to the at least one processing unit and storing instructions executable by the at least one processing unit, the instructions, when executed by the at least one processing unit, causing the device to perform the method according to claim 1.

15. The electronic device of claim 14, wherein the electronic device comprises a distance relay used in a power system.

16. A computer readable storage medium having computer readable program instructions stored thereon which, when executed by a processing unit, cause the processing unit to perform the method according to claim 1.

17. The electronic device of claim 14, wherein determining the at least one phase angle between the voltages at the first position and the estimated voltages at the second position comprises:
determining a first phase angle between the phase voltage of a first phase at the first position and the estimated phase voltage of the first phase at the second position; and
determining a second phase angle between the interphase voltage of a second phase to a third phase at the first position and the estimated interphase voltage of the second phase to the third phase at the second position.

18. The electronic device of claim 14, wherein determining the at least one phase angle between the voltages at the first position and the estimated voltages at the second position comprises:
for each of the three phases, determining a phase angle between the phase voltage of the respective phase at the first position and the estimated phase voltage of the same phase at the second position.

19. The electronic device of claim 14, wherein determining the at least one phase angle between the voltages at the first position and the estimated voltages at the second position comprises:
for each of three two-phase combinations, determining a phase angle between the interphase voltage of the respective two-phase combination at the first position and the estimated interphase voltage of the same two-phase combination at the second position.

20. The electronic device of claim 14, wherein determining the at least one phase angle between the voltages at the first position and the estimated voltages at the second position comprises:
for each of the three phases, determining a first phase angle between the phase voltage of the respective phase at the first position and the estimated phase voltage of the same phase at the second position;
for each of three two-phase combinations, determining a second phase angle between the interphase voltage of the respective two-phase combination at the first position and the estimated interphase voltage of the same two-phase combination at the second position; and
determining an average angle based on the first phase angles for the three phases and the second phase angles for the three two-phase combinations as the at least one phase angle.
